(19) United States
(12) Patent Application Publication
(10) Pub. No.: US 2025/0298060 A1
(43) Pub. Date: Sep. 25, 2025

(54) CURRENT SENSOR

(71) Applicant: Alps Alpine Co., Ltd., Tokyo (JP)

(72) Inventors: Ken CHIBA, Miyagi-ken (JP); Manabu TAMURA, Miyagi-ken (JP)

(21) Appl. No.: 19/230,583

(22) Filed: Jun. 6, 2025

Related U.S. Application Data
(63) Continuation of application No. PCT/JP2023/040148, filed on Nov. 8, 2023.

(30) Foreign Application Priority Data
Jan. 25, 2023 (JP) 2023-009438

(51) Int. Cl. G01R 15/20; G01R 19/00

(52) U.S. Cl. CPC G01R 15/207; G01R 19/0092

(57) ABSTRACT

A current sensor has a bus bar in which a current under measurement flows and also has a magnetic detection unit placed so as to face the bus bar, the magnetic detection unit sensing a magnetic field generated around the bus bar. The bus bar is formed from a laminate material in which a first metal material and a second metal material, which are different types of metal materials, are laminated. The first metal material has a larger density than the second metal material, and also has a smaller electrical resistivity than the second metal material. The magnetic detection unit is placed so as to face a surface of the bus bar, the surface being formed from the first metal material.

### CLAIM OF PRIORITY

This application is a Continuation of International Application No. PCT/JP2023/040148 filed on Nov. 8, 2023, which claims benefit of Japanese Patent Application No. 2023-009438 filed on Jan. 25, 2023. The entire contents of each application noted above are hereby incorporated by reference.

### BACKGROUND OF THE INVENTION

### 1. Field of the Invention

The present invention relates to a current sensor that detects a magnetic field generated when a current under measurement flows in a bus bar and that measures the current value of a measured current from the detected magnetic field.

### 2. Description of the Related Art

Recently, to control and monitor any type of unit, a current sensor is used that is attached to the unit and measures a current under measurement that flows in the unit. As a current sensor of this type, a known current sensor uses a magneto-electric conversion element that senses a magnetic field generated when a current under measurement flows in a bus bar used as a current path. To improve electricity consumption, requirements for current sensors such as for weight reduction and cost reduction are becoming more sophisticated and more advanced in response to an increase in electric cars and hybrid vehicles, which use a motor as a power source.

In a current sensor, described in Japanese Unexamined Patent Application Publication No. 2019-109126, which is intended for improving pulse response, the current sensor using bus bars, shield plates, magnetic detection elements, and a conductive plate, a plate-like superior electrical conductor, which is formed from a copper material, an aluminum material, or the like is used as the bus bar.

However, the current sensor described in Japanese Unexamined Patent Application Publication No. 2019-109126 uses a bus bar machined from a single superior electrical conductor. In the publication, there is no description of a bus bar's structure by which the weight and cost of the current sensor are reduced.

### SUMMARY OF THE INVENTION

In view of this, the present invention provides a current sensor having a bus bar effective for reducing its weight and cost.

The present invention has a structure below as a means for solving the problem described above.

A current sensor has a bus bar in which a current under measurement flows and also has a magnetic detection unit placed so as to face the bus bar, the magnetic detection unit sensing a magnetic field generated around the bus bar. The bus bar is formed from a laminate material in which a first metal material and a second metal material, which are different types of metal materials, are laminated. The first metal material has a larger density than the second metal material, and has a smaller electrical resistivity than the second metal material. The magnetic detection unit is placed so as to face a surface of the bus bar, the surface being formed from the first metal material.

Due to a structure in which two types of metal materials are laminated, a balance can be obtained between reduction in the amount of heat generated in the bus bar when a current under measurement flows and reduction in the weight of the bus bar by adjusting the ratio of metal materials having different densities and different electrical resistivities.

In the bus bar, in a lamination direction, the second metal material may have a larger dimension than the first metal material. In the bus bar, in a lamination direction, a dimension of the second metal material may be 80% or more of a dimension of the lamination material.

When the magnetic detection unit is placed so as to face a surface of the bus bar, the surface being formed from the first metal material, due to the above structure, it is possible to suppress heat generation, which is caused by a flow of a current under measurement, by use of the first metal material and to achieve weight reduction by use of the second metal material, while the frequency characteristics of the bus bar are kept high.

A current sensor has a bus bar in which a current under measurement flows and also has a magnetic detection unit placed so as to face the bus bar, the magnetic detection unit sensing a magnetic field generated around the bus bar. The bus bar is formed from a laminate material in which a first metal material and a second metal material, which are different types of metal materials, are laminated. The first metal material has a larger density than the second metal material, and has a smaller electrical resistivity than the second metal material. The magnetic detection unit is placed so as to face a surface of the bus bar, the surface being formed from the second metal material.

Due to a structure in which two types of metal materials are laminated, a balance can be obtained between reduction in the amount of heat generated in the bus bar when a current under measurement flows and reduction of the weight of the bus bar.

In the bus bar, in a lamination direction, the second metal material may have a larger dimension than the first metal material. In the bus bar, in a lamination direction, a dimension of the second metal material may be 60% or more of a dimension of the lamination material.

When the magnetic detection unit is placed so as to face a surface of the bus bar, the surface being formed from the second metal material, due to the above structure, it is possible to suppress heat generation, which is caused by a flow of a current under measurement, by use of the first metal material and to achieve weight reduction by use of the second metal material, while the frequency characteristics of the bus bar are kept high.

A current sensor has a plurality of measurement phases, each of which is composed of a bus bar in which a current under measurement flows, and also has a magnetic detection unit placed so as to face the bus bar, the magnetic detection unit sensing a magnetic field generated around the bus bar. The bus bar is formed from a laminate material in which a first metal material and a second metal material, which are different types of metal materials, are laminated. The first metal material has a larger density than the second metal material, and has a smaller electrical resistivity than the second metal material. The current sensor has a first measurement phase in which the magnetic detection unit is placed so as to face a surface of the bus bar, the surface being formed from the first metal material, and also has a second measurement phase in which the magnetic detection unit is placed so as to face a surface of the bus bar, the surface being formed from the second metal material.

Since the first metal material has a smaller electrical resistivity than the second metal material, much more current flows in the first metal material. Therefore, when the magnetic detection unit is placed so as to face a surface formed from the first metal material, magnetic field density sensed by the magnetic detection unit becomes large, so the sensing precision of the first measurement phase becomes superior to that of the second measurement phase. Therefore, when a measurement phase for which high precision is demanded is used as the first measurement phase, a plurality of measurement phases can be placed according to demanded sensing precision.

Second measurement phases may be adjacently placed on both sides of the first measurement phase. When three or more measurement phases are provided, measurement error becomes large in a measurement phase that is affected by measurement phases next to both sides of the measurement phase. Therefore, if measurement phases are adjacently provided on both sides, when the second measurement phase is used as each of the measurement phases on both sides and the first measurement phase is used as the measurement phase at the center, it is possible to suppress a drop in the sensing precision of the first measurement phase and to reduce a difference in measurement precision among a plurality of measurement phases.

In the bus bar, in a lamination direction, the second metal material may have a larger dimension than the first metal material. Due to this structure, a balance can be obtained between weight reduction by use of the second metal material and heat generation suppression by use of the first metal material, while the frequency characteristics of the bus bar are kept high because the first metal material is laminated on the second metal material.

In at least one measurement phase, the bus bar may have a bent portion. The magnetic detection unit may be placed at a position at which the magnetic detection unit can sense induced magnetic fields from two portions positioned with the bent portion interposed therebetween in the bus bar. Due to this structure, the magnetic detection unit can sense induced magnetic fields from two portions positioned with the bent portion interposed therebetween, so the sensing precision of the current sensor is improved.

In the bus bar, the first metal material may be provided on the side on which the bent portion is bent. The magnetic detection unit may face a layer of the first metal material of the bus bar. When the layer formed from the first metal material is provided on the side on which the bent portion is bent, the magnetic flux density of the induced magnetic field sensed by the magnetic detection unit becomes high, so the sensing precision of the current sensor is improved.

The first metal material may be a copper material, and the second metal material may be an aluminum material. When a copper material, the electrical resistivity of which is low, and an aluminum material, the density of which is small, are laminated, the bus bar becomes lightweight and has superior frequency characteristics, with heat generation suppressed.

According to the present invention, since a laminate material in which different types of metal materials are laminated is used, the property of the bus bar can be adjusted, so it becomes possible to provide a current sensor appropriate for downsizing and slimming down.

### BRIEF DESCRIPTION OF THE DRAWINGS

FIG. 1A is a plan view of a current sensor in a first embodiment;

FIG. 1B is a sectional view of the current sensor as taken along line IB-IB in FIG. 1A;

FIG. 2 is a graph illustrating simulation results for the ratio of a thickness T4 of an Al material to a total thickness T1 and for bus bar phase characteristics when the bus bar in FIG. 1B is formed from a Cu material and an Al material;

FIG. 3 is a sectional view of the current sensor, in FIG. 1B, in which magnetic shields are provided;

FIG. 4 is a sectional view of a current sensor in a second embodiment;

FIG. 5 is a graph illustrating simulation results for the ratio of the thickness T4 of an Al material to the total thickness T1 and for bus bar phase characteristics when the bus bar in FIG. 4 is formed from a Cu material and an Al material;

FIG. 6 is a sectional view of the current sensor, in FIG. 4, in which magnetic shields are provided;

FIG. 7A is a graph illustrating differences in magnetic flux density due to a lamination order and Al ratio in a bus bar in which an Al material and a Cu material are laminated;

FIG. 7B is a graph illustrating differences in influence on an adjacent bus bar due to a lamination order and Al ratio in a bus bar in which an Al material and a Cu material are laminated;

FIG. 8 is a sectional view of a current sensor of multi-phase type in a third embodiment;

FIG. 9 is a perspective view of a current sensor of multi-phase type in a variation;

FIG. 10 is a perspective view of a current sensor of multi-phase type in another variation;

FIG. 11A is a plan view of a current sensor in a reference example;

FIG. 11B is a sectional view of the current sensor as taken along line XIB-XIB in

FIG. 11A;

FIG. 12A is a graph illustrating the relationship between the frequency and phase angle of a current flowing in the bus bar in the reference example in FIG. 11A;

FIG. 12B is a graph illustrating the relationship between the frequency and gain of a current flowing in the bus bar in the reference example in FIG. 11A;

FIG. 13A is a graph illustrating temperature changes accompanying the elapse of time when a current under measurement flows, in a conventional bus bar, in which a tightening portion is formed from an Al material and a main body is formed from an Al material;

FIG. 13B is a graph illustrating temperature changes accompanying the elapse of time when a current under measurement flows, in the conventional bus bar, in which the tightening portion is formed from a Cu material and the main body is formed from a Cu material;

FIG. 13C is a graph illustrating temperature changes accompanying the elapse of time when a current under measurement flows in the bus bar, in the reference example, in which the tightening portion is formed from a Cu material and the main body is formed from an Al material;

FIG. 14A is a plan view of a current sensor in another reference example;

FIG. 14B is a sectional view of the current sensor as taken along line XIVB-XIVB in FIG. 14A;

FIG. 15A is a plan view of a conventional current sensor;

FIG. 15B is a sectional view of the current sensor as taken along line XVB-XVB in

FIG. 15A; and

FIG. 15C is a sectional view of the current sensor as taken along line XVC-VC in FIG. 15A.

### DESCRIPTION OF THE PREFERRED EMBODIMENTS

Embodiments of the present invention will be described below with reference to the attached drawings. Identical members are assigned identical numerals on each drawing, and descriptions will be omitted. A reference coordinate system is appropriately indicated on each drawing to indicate the positional relationship among members. In the reference coordinate system, the direction in which the bus bar extends is the X direction; the direction orthogonal to the X direction on the facing surface of the bus bar, the facing surface facing a magnetic detection unit, is the Y direction; and the direction orthogonal to the X direction and Y direction is the Z direction. The Y direction matches the direction of the sensitivity axis of the magnetic detection unit. The X direction and Z direction are orthogonal to the sensitivity axis.

### First Embodiment

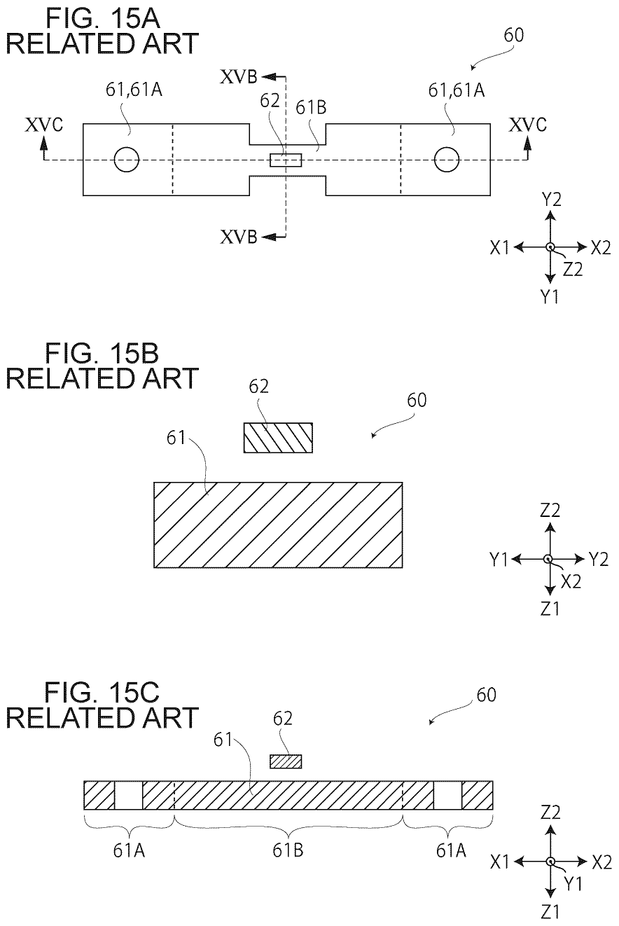

FIG. 15A is a plan view of a conventional current sensor 60. FIG. 15B is a sectional view of the current sensor 60 as taken along line XVB-XVB in FIG. 15A. As illustrated in these drawings, in the conventional current sensor 60, which has a bus bar 61 and a magnetic detection unit 62, a plate-like electrical conductor is used as the bus bar 61, in which a current under measurement flows. Materials of the electrical conductor include copper materials and aluminum materials. A copper material, which is superior in conductivity, is often used alone. However, when the bus bar 61 is formed from only a copper material, it may be difficult to satisfy more sophisticated and more advanced requirements for current sensors, such as for weight reduction and cost reduction. In view of this, the present invention uses a bus bar formed from a laminate material in which different types of metal materials are laminated to achieve downsizing and slimming down of the current sensor.

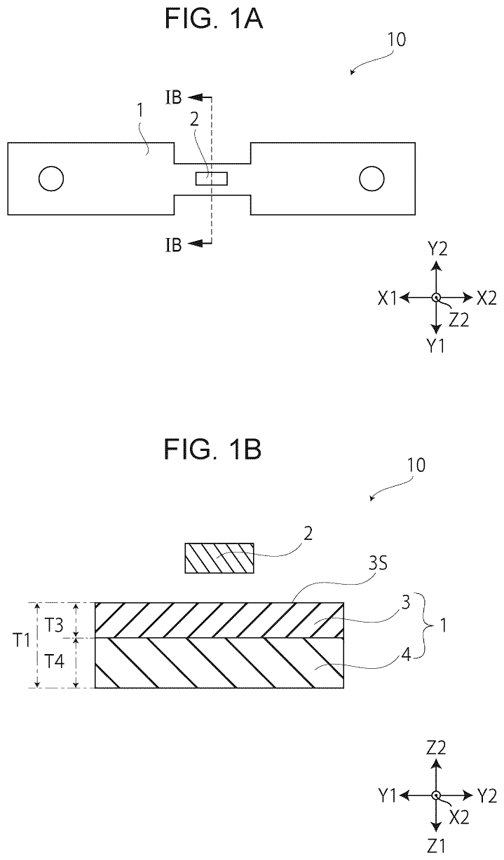

FIG. 1A is a plan view of a current sensor 10 in this embodiment. FIG. 1B is a sectional view of the current sensor 10 as taken along line IB-IB in FIG. 1A. As illustrated in these drawings, the current sensor 10 has a bus bar 1, in which a current under measurement flows, and also has a magnetic detection unit 2 placed so as to face the bus bar 1, the magnetic detection unit 2 sensing a magnetic field generated around the bus bar 1.

The bus bar 1 is formed from a laminate material in which a first metal material 3 and a second metal material 4, which are different types of metal materials, are laminated. In the bus bar 1 in this embodiment, each of the first metal material 3 and second metal material 4 is structured as a layer having a uniform thickness in the Z direction.

The first metal material 3 has a larger density than the second metal material 4 (in other words, the first metal material 3 is heavier than the second metal material 4), and has a smaller electrical resistivity (appropriately referred to below as resistivity) than the second metal material 4.

The magnetic detection unit 2 in the current sensor 10 is placed so as to face a surface 3S of the bus bar 1, the surface 3S being formed from the first metal material 3.

A copper material, for example, can be used as the first metal material 3, and an aluminum material can be used as the second metal material 4. Copper materials refer to pure copper materials, copper alloys, and conductive materials including pure copper materials and copper alloys. Aluminum materials refer to pure aluminum materials, aluminum alloys, and conductive materials including pure aluminum materials and aluminum alloys.

In the description below, a Cu (pure copper) material is used as a copper material and an Al (pure aluminum) material is used as an aluminum material, as an example. Since an Al material has a smaller specific gravity and density than a Cu material and is more inexpensive than the Cu material, a bus bar formed from an Al material is more advantageous than a bus bar formed from a Cu material in terms of weight reduction and cost reduction.

However, since the resistivity of the Al material is 2.65×10-8 [Ω·m], which is larger than the resistivity of the Cu material, 1.68×10-8 [Ω·m], if the material of the bus bar 1 is an Al material, the resistivity of the bus bar 1 becomes large. Therefore, the temperature of the magnetic detection unit 2 rises due to the influence of heat generation in the bus bar 1 when a current under measurement flows. This may cause the problem that if the heat-resistant temperature of the magnetic detection unit 2 is exceeded, the detection precision of the current sensor 10 is lowered.

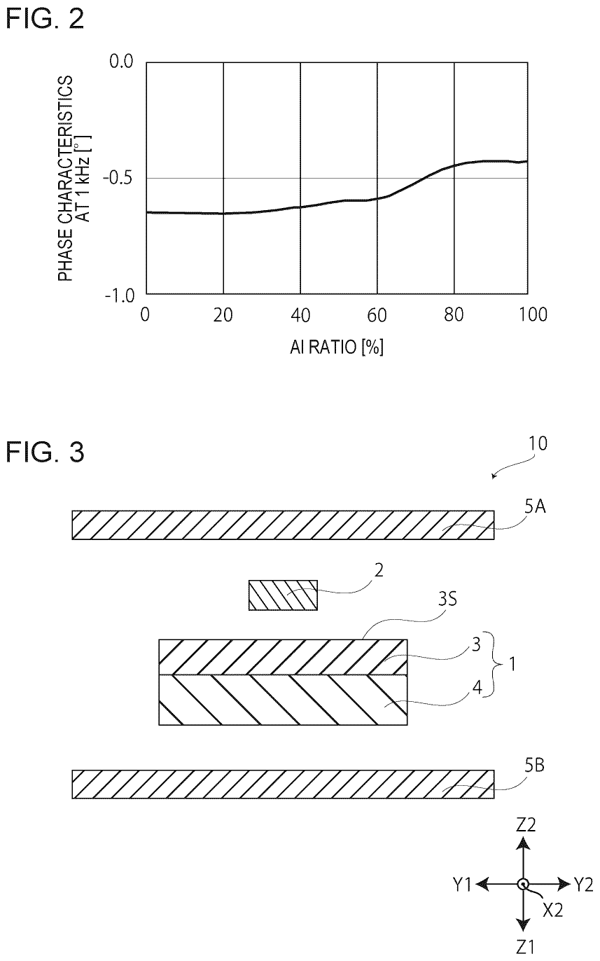

FIG. 2 is a graph illustrating results of a simulation in which a Cu material was used as the first metal material 3 and an Al material was used as the second metal material 4 for the bus bar 1, illustrated in FIG. 1B, formed from a laminate material. In the simulation, a thickness T3 of the Cu material and a thickness T4 of the Al material in the Z direction were changed. The horizontal axis in the drawing indicates the ratio, T4/T1×100(%), of the thickness T4 of the Al material to the total T1 (=T3+T4) of the thicknesses of the Cu material and Al material.

The bus bar 1, for which the simulation in FIG. 2 was performed, has a laminate structure illustrated in FIG. 1B. A Cu layer is placed as the first metal material 3 on the Z2 side, which is on the same side as the magnetic detection unit 2. An Al layer is placed as the second metal material 4 on the Z1 side, which is opposite to the magnetic detection unit 2.

In the graph in FIG. 2, the state when the phase characteristics on the vertical axis is 0.0° is an ideal state, in which there is no delay of an output voltage from the current sensor 10 with respect to the current under measurement. The graph indicates that the lower (the more toward −1.0°) the value of the vertical axis is, the greater the delay of the output voltage is. When this delay is great, a time delay of the output voltage from the current sensor 10 with respect to the current under measurement becomes large in a high-frequency band. Therefore, it can be said that the phase characteristics on the vertical axis are preferably closer to 0.0°. This graph indicates that the delay of the output voltage from the current sensor 10 was the smallest when the bus bar 1 with an Al ratio of 100% was provided and that an inflection point of the phase characteristics was present at an Al ratio from 60% to 80%.

It can be said from the results illustrated in FIG. 2 that the thickness T4, which is a dimension of the second metal material 4 in the Z direction matching the lamination direction, is preferably larger than the thickness T3, which is a dimension of the first metal material 3, from the viewpoint of suppressing deterioration in the frequency characteristics of the bus bar 1, the deterioration being related to the delay of the output voltage from the current sensor 10, and achieving weight reduction. When the thickness T1 (=T3+T4), which is a dimension of the bus bar 1, formed from a laminate material, in the lamination direction is 100%, the thickness T4 of the second metal material 4 is more preferably 80% or more.

FIG. 3 is a sectional view of the current sensor 10 in which magnetic shields 5A and 5B are provided. As illustrated in the drawing, in the current sensor 10, the magnetic shields 5A and 5B may be disposed on both sides in the Z direction so that the bus bar 1 and magnetic detection unit 2 are interposed therebetween. Due to the magnetic shields 5A and 5B, it is possible to restrain magnetic noise from entering the magnetic detection unit 2 from the outside, so the measurement precision of the current sensor 10 is improved. A structure may be taken in which a magnetic shield is provided only on the Z1 side of the bus bar 1 or only on the Z2 side of the magnetic detection unit 2 (a structure may be taken in which any one of the magnetic shields 5A and 5B is provided).

As the magnetic shields 5A and 5B, a stack of a plurality of metal plate-like bodies having the same shape is used, for example. In each drawing referenced in explanation, a stack of a plurality of plate-like bodies is simplified to one plate-like body to illustrate the magnetic shield 5A or 5B.

A magnetic shield of U-shaped type, which has a U-shaped cross section along line IB-IB in FIG. 1A, may be used instead of the magnetic shield 5A or 5B of flat-plate type illustrated in FIG. 3. Specifically, a magnetic shield of U-shaped type may be used that encloses the magnetic detection unit 2 in a structure in which the bus bar 1 has a U shape formed on both sides of the bus bar 1 in the Y direction and on its Z1-direction side.

### Second Embodiment

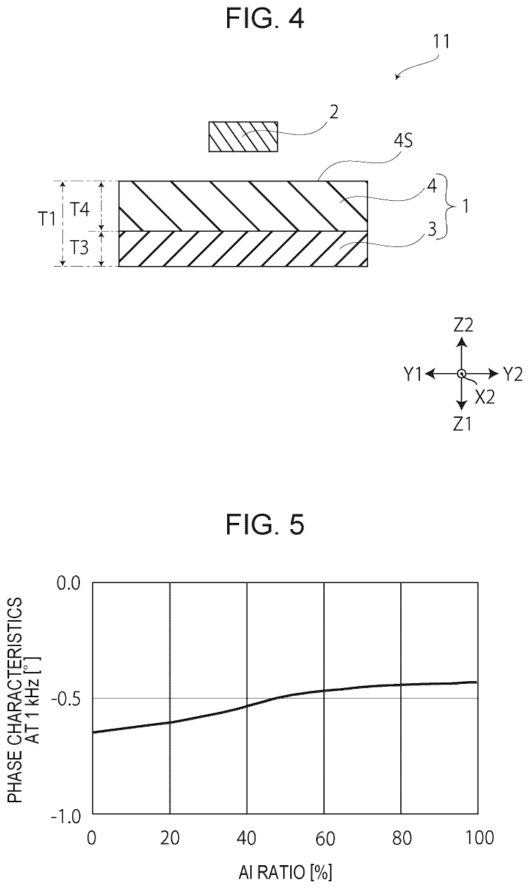

FIG. 4 is a sectional view of a current sensor 11 in this embodiment. The current sensor 11 in this embodiment is the same as before in that the laminate material forming the bus bar 1 is a stack of the first metal material 3 and second metal material 4. However, the current sensor 11 differs from the current sensor 10 in that the magnetic detection unit 2 is placed so as to face a surface 4S of the bus bar 1, the surface 4S being formed from the second metal material 4; in the current sensor 10, the magnetic detection unit 2 is placed so as to face the surface 3S of the bus bar 1, the surface 3S being formed from the first metal material 3.

FIG. 5 is a graph illustrating results of a simulation in which a lamination material composed of a Cu material as the first metal material 3 and an Al material as the second metal material 4 was used to form the bus bar 1 illustrated in FIG. 4. In the simulation, the thickness T3 of the Cu material and the thickness T4 of the Al material in the Z direction were changed. The horizontal axis in the drawing indicates the ratio of the thickness T4 of the Al material to the thickness T1 of the bus bar 1.

The bus bar 1 for which a simulation, results of which are illustrated in FIG. 5, was performed has the laminate structure illustrated in FIG. 4; an Al layer is placed as the second metal material 4 on the same side as the magnetic detection unit 2, and a Cu layer is placed as the first metal material 3 on the opposite side of the magnetic detection unit 2 with the layer of the second metal material 4 interposed therebetween.

The vertical axis and horizontal axis of the graph in FIG. 5 each indicate the same label as in the graph in FIG. 2. This graph indicates that the delay of the output voltage from the current sensor 10 was the smallest when the bus bar 1 with an Al ratio of 100% was provided and that there was an inflection point of the phase characteristics at an Al ratio from 40% to 60%.

It can be said from the results illustrated in FIG. 5 that when the magnetic detection unit 2 is placed so as to face the surface 4S of the Al layer, which is used as the second metal material 4, the thickness T4, which is a dimension of the second metal material 4 in the Z direction matching the lamination direction, is preferably larger than the thickness T3, which is a dimension of the first metal material 3, from the viewpoint of suppressing deterioration in the frequency characteristics of the bus bar 1, the deterioration being related to the delay of the output voltage from the current sensor 10, and achieving weight reduction. When the thickness T1, which a dimension of the bus bar 1, formed from a laminate material, in the lamination direction is 100%, the thickness T4 of the second metal material 4 is more preferably 60% or more.

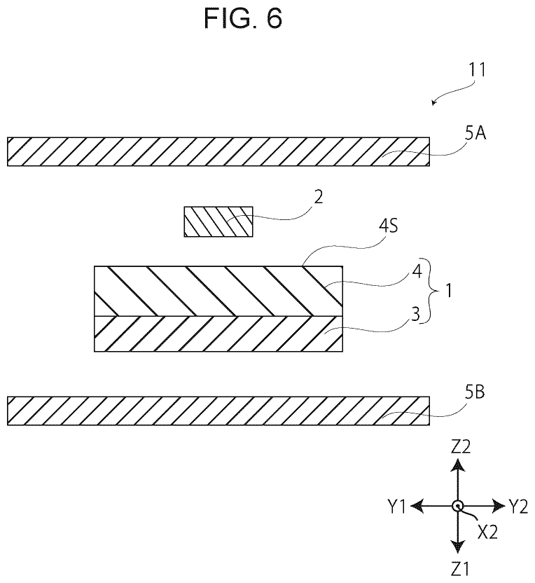

FIG. 6 is a sectional view of the current sensor 11 in which the magnetic shields 5A and 5B are provided. As illustrated in the drawing, in the current sensor 11, the magnetic shields 5A and 5B may be disposed on both sides in the Z direction so that the bus bar 1 and magnetic detection unit 2 are interposed therebetween. Due to the magnetic shields 5A and 5B, it is possible to restrain magnetic noise from entering the magnetic detection unit 2 from the outside, so the measurement precision of the current sensor 11 is improved.

The current sensors, described above, in the first and second embodiments each have a bus bar formed by laminating two types of metal materials. Thus, it is possible to achieve reduction in the amount of heat generated in the bus bar when a current under measurement flows and weight reduction of the bus bar, by adjusting the ratio of the metal materials having different densities and electrical resistivities.

### Third Embodiment

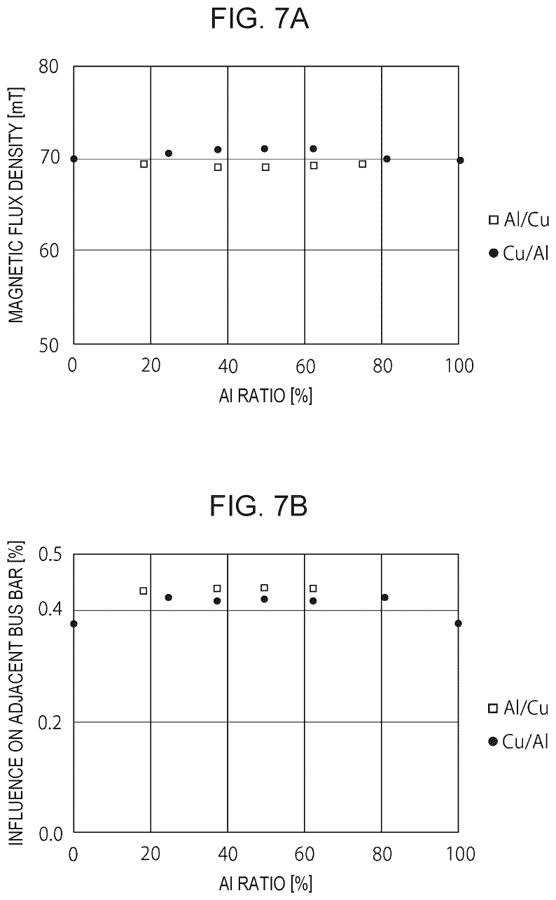

In this embodiment, an aspect that practices the present invention as a current sensor of multi-phase type. FIG. 7A is a graph of simulation results illustrating differences in magnetic flux density in the vicinity of the bus bar 1 when in a current sensor of multi-phase type having a plurality of measurement phases, a Cu material is used as the first metal material 3 and an Al material is used as the second metal material 4, the differences being caused due to an Al ratio and the lamination order of the Al and Cu materials. The Al ratio in the drawing indicates the same as in the simulation related to the frequency characteristics in the first and second embodiments.

Results indicated as Cu/Al are results of a simulation for the current sensor 10 (see FIG. 1B), in which the magnetic detection unit 2 is disposed so as to face the surface 3S on the same side as the Cu material used as the first metal material 3.

Results indicated as Al/Cu are results of a simulation for the current sensor 11 (see FIG. 4), in which the magnetic detection unit 2 is disposed so as to face the surface 4S on the same side as the Al material used as the second metal material 4. The simulation for Cu/Al and the simulation for Al/Cu were performed under the same conditions except the lamination order.

It was found that the magnetic flux density in the vicinity of the bus bar 1 varied as illustrated in FIG. 7A, depending on which surface, the surface 3S on the Cu side or the surface 4S on the Al side, the magnetic detection unit 2 is disposed on. A possible cause for these results is that when a current under measurement flows in the bus bar 1 formed from a laminate material formed from different types of metals, much more current flows on the Cu side, on which electrical resistivity is low, than on the Al side, on which electrical resistivity is high.

It was also found from the results indicated as Cu/Al that when a laminate material was used, magnetic flux density became higher than when the bus bar 1 was formed from only a Cu material (Al ratio of 0%) and than when the bus bar 1 was formed from only an Al material (Al ratio of 100%). When the bus bar 1 is formed from a laminate material in this way, magnetic flux density detected by the magnetic detection unit 2 becomes large and the measurement precision of the current sensor 10 is improved.

FIG. 7B is a graph illustrating, in a current sensor of multi-phase type having a plurality of measurement phases, differences in the influence of the Al ratio and the lamination order of the Al and Cu materials on an adjacent bus bar. The results in the drawing indicate the magnitude of error caused in the current sensor at the center when three current sensors having bus bars formed from the same laminate material were arranged side by side and measurement was performed under the same condition. Also, Cu/Al and Al/Cu indicate a difference in the lamination order, which has been described with reference to FIG. 7A, of the bus bar.

It was found from the results, indicated in FIG. 7B, for Cu/Al that when the bus bar in a current sensor of multi-phase type was formed from a laminate material, the bus bar was more greatly affected by an adjacent bus bar than when the bus bar was formed from only a Cu material (Al ratio of 0%) and than when the bus bar was formed from only an Al material (Al ratio of 100%). For this, it can be considered that by using, as a bus bar, a laminate material in which different types of metal materials are laminated, a difference in magnetic flux density in the Z direction in an induced magnetic field generated when a current under measurement flows became larger than in a bus bar for which a material of a single type of metal material was used.

Also, it was found from the results illustrated in FIG. 7B, the influence from the adjacent bus bar was smaller in Cu/Al, in which the magnetic detection unit 2 was disposed so as to face the surface 3S on the Cu side than in Al/Cu, in which the magnetic detection unit 2 was disposed so as to face the surface 4S on the Al side. A possible cause for this is that in the bus bar 1, the current density of the current under measurement that flows in the first metal material 3, the electrical resistivity of which is low, became higher than the current density of the current under measurement that flows in the second metal material 4, the electrical resistivity of which is high, and thereby the magnetic flux density measured by the magnetic detection unit 2 became high.

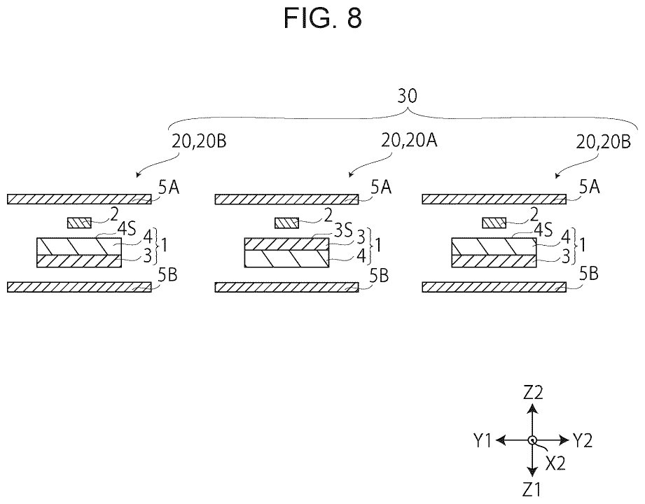

FIG. 8 is a sectional view illustrating a current sensor 30 of multi-phase type in this embodiment. As illustrated in the drawing, the current sensor 30 has a plurality of measurement phases 20, each of which is composed of the bus bar 1, in which a current under measurement flows, and also has the magnetic detection unit 2 placed so as to face the bus bar 1, the magnetic detection unit 2 sensing a magnetic field generated around the bus bar 1.

The current sensor 30 has a first measurement phase 20A, in which the magnetic detection unit 2 is placed so as to face the surface 3S of the bus bar 1, the surface 3S being formed from the first metal material 3, and second measurement phases 20B, in each of which the magnetic detection unit 2 is placed so as to face the surface 4S of the bus bar 1, the surface 4S being formed from the second metal material 4.

Since the first metal material 3 has a smaller electrical resistivity than the second metal material 4, much more current flows in the first metal material 3. Therefore, when the magnetic detection unit 2 is placed so as to face the surface 3S formed from the first metal material 3, the magnetic field density of the induced magnetic field generated by a current under measurement becomes large, the induced magnetic field being sensed by the magnetic detection unit 2. Therefore, the sensing precision of the first measurement phase 20A becomes superior to that of the second measurement phases 20B.

For example, when a different level of sensing precision is demanded for each measurement phase 20 in the current sensor 30 having a plurality of measurement phases 20, it is possible to select the first measurement phase 20A or second measurement phases 20B and place it, depending on necessary sensing precision.

In the current sensor 30 illustrated in FIG. 8, three measurement phases 20 are placed side by side in the Y direction. Of the three measurement phases 20, the measurement phase 20 placed at the center affected by the measurement phases 20, to which the measurement phase 20 at the center is adjacent on both sides in the Y direction, so error of the measurement phase 20 becomes large. In view of this, the first measurement phase 20A is preferably used as the measurement phase 20 at the center and the second measurement phase 20B is preferably used as each of the measurement phases 20 on both sides, it is possible to suppress a drop in the sensing precision of the measurement phase 20 at the center and to reduce differences in measurement precision among a plurality of measurement phases 20.

In all of the plurality of measurement phases 20 in the current sensor 30, the magnetic detection unit 2 is disposed on the same side of the bus bar 1 (in FIG. 8, on the Z2 side). Due to a structure in which the second measurement phases 20B are adjacently placed on both sides of the first measurement phase 20A, the distance is prolonged between the magnetic detection unit 2 in the first measurement phase 20A and the first metal material 3 of the bus bar 1 in the second measurement phase 20B on each side. In the bus bar 1, the current under measurement flows much more in the first metal material 3, so the distance is prolonged between a source from which an induced magnetic field is generated in the second measurement phase 20B placed on each side of the first measurement phase 20A and the magnetic detection unit 2 in the first measurement phase 20A placed at the center. Therefore, it is possible to reduce the influence of a magnetic field from the bus bar 1 in the second measurement phases 20B, next to the first measurement phase 20A, on the first measurement phase 20A. Thus, in the bus bar 1 in the second measurement phase 20B adjacently placed on each side of the first measurement phase 20A, the first metal material 3 is preferably laminated on the Z1 side, on which the distance from the magnetic detection unit 2 in the first measurement phase 20A is long.

In the current sensor 30, illustrated in FIG. 8, which has a plurality of measurement phases 20, the thickness T4 of the second metal material 4 is preferably larger than the thickness T3 (see FIGS. 1B and 4) of the first metal material 3 in the Z direction matching the lamination direction of the first metal material 3 and second metal material 4, from the viewpoint of making frequency characteristics superior.

When the magnetic detection unit 2 faces the surface 3S formed from the first metal material 3, the ratio of the thickness T4 of the second metal material 4 to the thickness of the bus bar 1 in the lamination direction is preferably larger than 50% and is more preferably 80% or more, as described in the first and second embodiments. When the magnetic detection unit 2 faces the surface 4S formed from the second metal material 4, the ratio of the thickness T4 of the second metal material 4 to the thickness of the bus bar 1 in the lamination direction is preferably larger than 50% and is more preferably 60% or more, as described in the first and second embodiments.

In the structure, described above, in which in the measurement phase 20 at the center of the three adjacent measurement phases 20, the measurement phase 20 at the center being likely to be affected by the induced magnetic field of the adjacent measurement phases 20, the first metal material 3 is placed on the same side as the magnetic detection unit 2 in the bus bar 1, and in the measurement phases 20 on both sides, the second metal material 4 is placed on the same side as the magnetic detection unit 2 in the bus bar 1. Due to this structure, it is possible to reduce the influence from the adjacent bus bars 1 on the magnetic detection unit 2 facing the bus bar 1 at the center.

When a current sensor is formed from two measurement phases 20 adjacent to each other, a structure can be formed in response to demanded precision by using, as the first measurement phase 20A, a measurement phase 20 for which relatively high precision is demanded and by using, as the second measurement phases 20B, a measurement phase 20 for which low precision is demanded.

### Variations

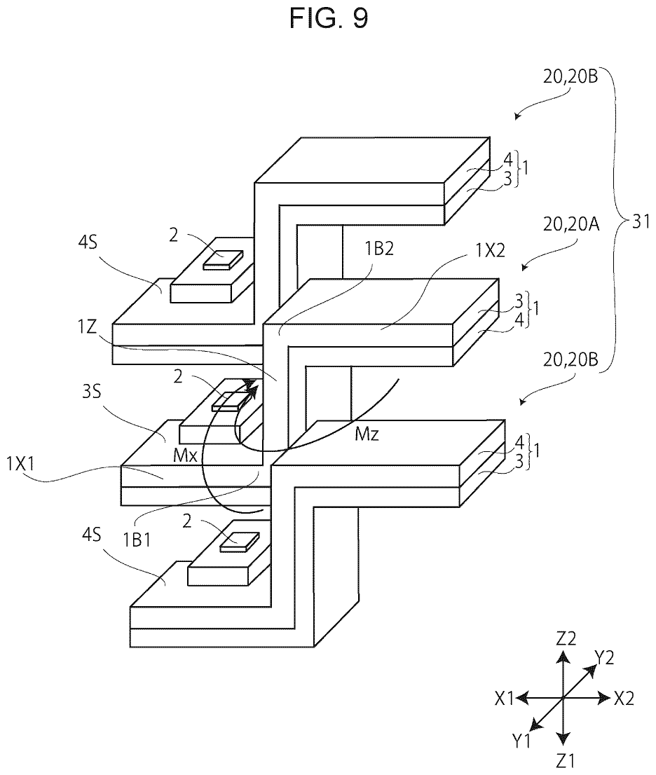

FIG. 9 a perspective view illustrating a current sensor 31 of multi-phase type in a variation. In the current sensor 31, the measurement phase 20 at the center of the three adjacent measurement phases 20 is the first measurement phase 20A and the measurement phases 20 on both sides are second measurement phases 20B. The bus bar 1 has a first portion 1X1 and first portion 1X2, which extend in the X direction, and also has a second portion 1Z extending in the Z direction. The first portion 1X1 and second portion 1Z are linked together through a bent portion 1B1, and the first portion 1X2 and second portion 1Z are linked together through a bent portion 1B2. The bus bar 1 is structured in a crank shape in which the bent portion 1B1 and bent portion 1B2 are bent through 90 degrees in opposite directions when viewed from the Y direction.

The bus bar 1 in the first measurement phase 20A has the bent portion 1B2 on the Z2-direction side, the bent portion 1B2 linking the second portion 1Z and the first portion 1X2 together, the first portion 1X2 extending from the Z2-direction end of the second portion 1Z toward the X2 side, and also has the bent portion 1B1 on the Z1-direction side, the bent portion 1B1 linking the second portion 1Z and the first portion 1X1 together, the first portion 1X1 extending from the Z1-direction end of the second portion 1Z toward the X1 direction. At the bent portion 1B2 on the Z2-direction side, the second metal material 4 is inside the bent portion 1B2. At the bent portion 1B1 on the Z1-direction side, the first metal material 3 is inside the bent portion 1B1.

FIG. 9 showed the bus bar 1 that has two first portions, 1X1 and 1X2, and the second portion 1Z and also has the bent portion 1B1 and bent portion 1B2 at both ends of the second portion 1Z in the Z direction. However, a structure may be taken in which only the first portion 1X1, second portion 1Z, and bent portion 1B1 are included or in which only the first portion 1X2, second portion 1Z, and bent portion 1B2 are included. Although an aspect has been indicated in which all of the three measurement phases 20 have the bent portion 1B1 and bent portion 1B2, a structure may be taken in which one or two of the three measurement phases 20 have at least one of the bent portion 1B1 and bent portion 1B2. When the bus bar 1 has only the bent portion 1B1 or bent portion 1B2, the magnetic detection unit 2 is placed on the side on which the bent portion 1B1 or bent portion 1B2 is bent, that is, inside it.

The magnetic detection unit 2 is preferably placed at a position at which the magnetic detection unit 2 can sense an induced magnetic field Mx and an induced magnetic field Mz respectively from the first portion 1X1 and second portion 1Z, which are continuous to the bent portion 1B1. Two portions of the bus bar 1 between which the bent portion 1B1 is interposed are the first portion 1X1 and second portion 1Z, which are continuous to the bent portion 1B1.

The induced magnetic field Mx and induced magnetic field Mz in this variation each include a Y-direction component. The magnetic detection unit 2 is placed so that the sensing direction of the magnetic detection unit 2 becomes parallel to the Y direction. That is, the magnetic detection unit 2 senses a combined component of the Y-direction component of the induced magnetic field Mx and the Y-direction component of the induced magnetic field Mz.

The magnetic detection unit 2 is positioned so that the induced magnetic field Mx and induced magnetic field Mz described above can be sensed. The magnitude of the combined component of the Y-direction component of the induced magnetic field Mx and the Y-direction component of the induced magnetic field Mz is preferably large enough for the magnetic detection unit 2 to be easily capable of sensing the combined component. Due to this structure, it is possible to efficiently detect the induced magnetic field generated when a current under measurement flows in the bus bar 1 by use of the magnetic detection unit 2. Since the magnetic detection unit 2 in the first measurement phase 20A at the center is placed so as to face the surface 3S of the bus bar 1, the surface 3S being a layer of the first metal material 3, the magnetic flux density of a magnetic field is high, the magnetic field being generated when a current under measurement flows. Therefore, the magnetic sensing precision of the magnetic detection unit 2 is improved.

Due to the structure in which the second measurement phase 20B is adjacently placed on each side of the first measurement phase 20A, when the magnetic detection unit 2 is disposed on the same side as the bus bar 1 in the Z direction, the distance between the magnetic detection unit 2 in the first measurement phase 20A and the first metal material 3 of the bus bar 1 in the second measurement phase 20B is prolonged. Thus, it is possible to reduce the influence of a magnetic field from the second measurement phases 20B on the first measurement phase 20A at the center. Since this effect is obtained at the first portion 1X1 and second portion 1Z, detection precision of the current sensor 31 becomes superior.

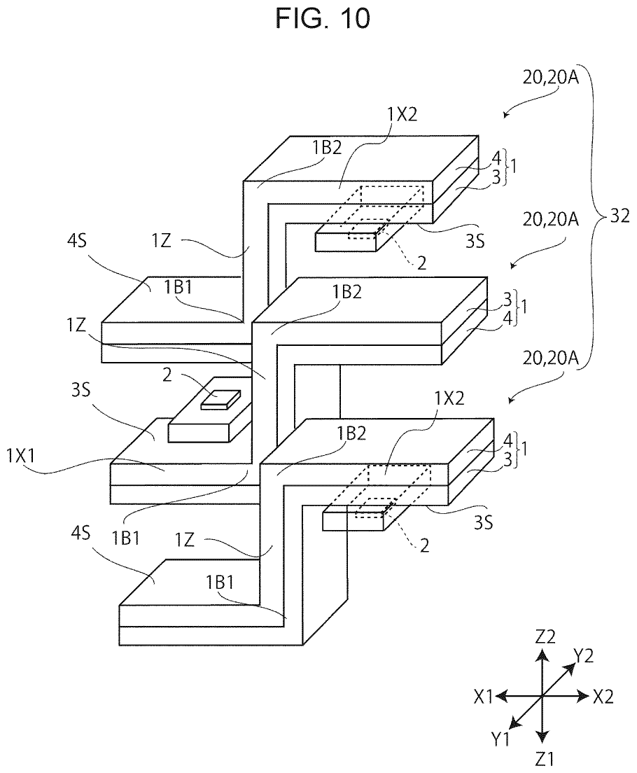

FIG. 10 is a perspective view illustrating a current sensor 32 of multi-phase type in another variation. The current sensor 32 illustrated in the drawing differs from the current sensor 31 in FIG. 9 in a structure in which in the measurement phases 20 on both sides, the magnetic detection unit 2 is placed inside the bent portion 1B2.

In the current sensor 32, the bus bars 1 in the three measurement phases 20 placed side by side are placed as in the variation illustrated in FIG. 9. In the measurement phase 20 at the center, the magnetic detection unit 2 is placed so as to face the first portion 1X1 on the Z1 side and the surface 3S of the layer of the first metal material 3 of the second portion 1Z, as in the variation illustrated in FIG. 9. In contrast to this, in the measurement phases 20 on both sides, the magnetic detection unit 2 is placed so as to face the first portion 1X2 of the bus bar 1 on the Z2 side and the surface 3S of the layer of the first metal material 3 of the second portion 1Z. That is, the magnetic detection unit 2 is placed so that all of the three measurement phases 20 placed side by side become the first measurement phase 20A. When the magnetic detection units 2 in the measurement phases 20 on both sides are placed so as to face the surface 3S of the bus bar 1, the surface 3S being formed from the first metal material 3, in this way, the magnetic flux density detected by the magnetic detection unit 2 becomes large and the sensing precision of the measurement phase 20 is improved.

### REFERENCE EXAMPLE

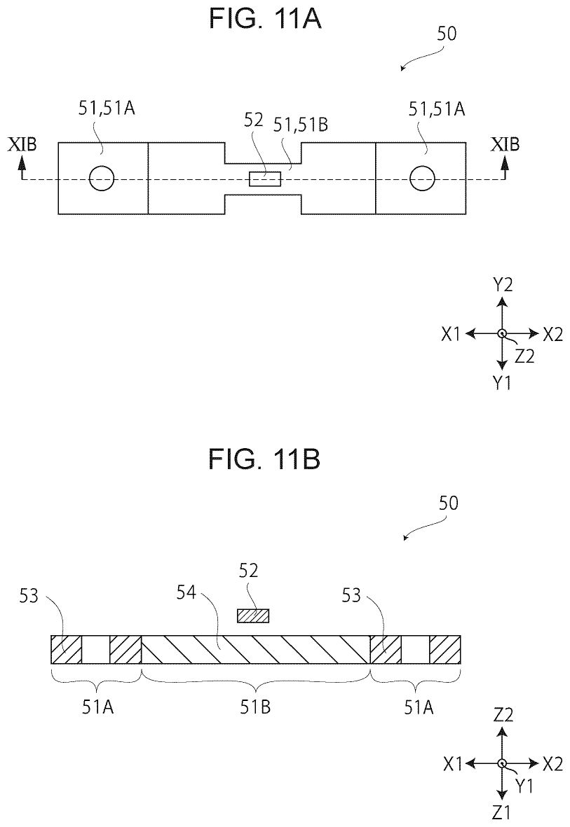

FIG. 11A is a plan view of a current sensor 50 in a reference example. FIG. 11B is a sectional view of the current sensor 50 as taken along line along line XIB-XIB in FIG. 11A.

As illustrated in these drawings, in the current sensor 50, a magnetic detection unit 52 is placed so as to face a bus bar 51. In the bus bar 1 in the current sensor 50, tightening portions 51A and a main body 51B including a narrowly constricted portion facing the magnetic detection unit 52 are formed from different types of metal materials.

For example, the tightening portion 51A is formed from a Cu material used as a first metal material 53, and the main body 51B is from an Al material used as a second metal material 54. Due to this, it is possible to reduce the contact resistance of the tightening portion 51A and suppress heat generation by a current under measurement unlike when tightening portions 61A and main body 61B of the bus bar 61 in the conventional current sensor 60 illustrated in FIG. 15C are formed from an Al material. Since the skin effect in the bus bar 51 is suppressed, it is possible to improve the frequency characteristics of magnetic flux density detected by the magnetic detection unit 52.

Tables below indicate frequency characteristics (phase characteristics) of a Cu material and an Al material.

TABLE 1

| | | Cu | Al |
|---|---|---|---|
| Phase Angle at 1 kHz | deg | −0.64 | −0.43 |

TABLE 2

Skin Depth (mm)

| | Cu | Al |
|---|---|---|
| 1 kHz | 2.1 | 2.7 |

The skin depth in Table 2 is a distance over which a magnetic field that has entered a certain material is attenuated to 1/e (≈1/2.718≈−8.7 db). When a high-frequency current flows in a conductor, most of the current concentrates on a very narrow area near the surface of the conductor. This means that the resistance of the conductor is essentially increased at high frequencies and that although reduction in resistance is expected at low frequencies by thickening the conductor, the thickening of the conductor to reduce resistance is not effective at high frequencies. Therefore, it can be said that an Al material with a large skin depth is more preferable than a Cu material from the viewpoint of frequency characteristics.

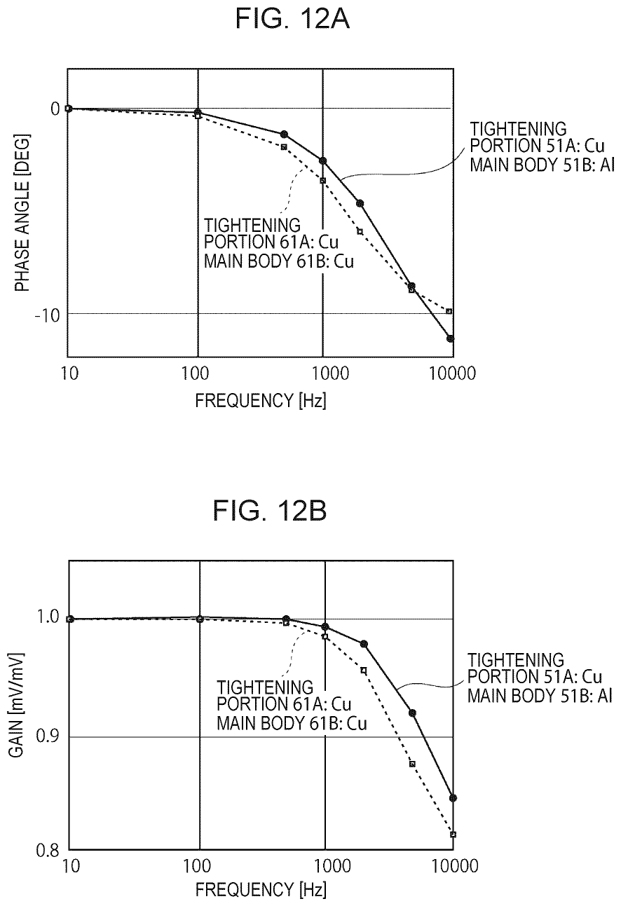

FIG. 12A is a graph illustrating simulation results about the relationship between the frequency phase angle of a current under measurement for the current sensor 50, in the reference example, which has the bus bar 51 with the tightening portion 51A formed from a Cu material and the main body 51B formed from an Al material and for the current sensor 60 having the bus bar 61 with the tightening portion 61A and main body 61B formed from a Cu material.

The graph in FIG. 12A represents a state in which the larger the value of the vertical axis (phase angle) is (the closer the value is to 0), the smaller the delay of the detection voltage with respect to the current under measurement is, that is, represents a superior state. It is found from this graph that even when the frequency of the current under measurement becomes high, the phase angle in the current sensor 50 remains larger and the detection voltage is less delayed with respect to the current under measurement than in the current sensor 60.

FIG. 12B is a graph illustrating simulation results about the relationship between the frequency and gain of a current under measurement for the current sensor 50, in the reference example illustrated in FIGS. 11A and 11B and for the current sensor 60 illustrated in FIGS. 15A to 15C.

The graph in FIG. 12B represents a state in which the larger the value (gain) of the vertical axis is (the closer the value is to 1), the more the detection voltage equivalent to the current under measurement is output, that is, represents a superior state. It is found from this graph that even when the frequency of the current under measurement becomes high, in the current sensor 50, the value of the vertical axis remains larger and much more detection voltage equivalent to the current under measurement is output than in the current sensor 60.

It is found from the results in the graphs illustrated in FIGS. 12A and 12B that when the material of the main body 61B of the bus bar 61 is changed from a Cu material to an Al material, the delay of the detection voltage with respect to the current under measurement is reduced and the gain is improved.

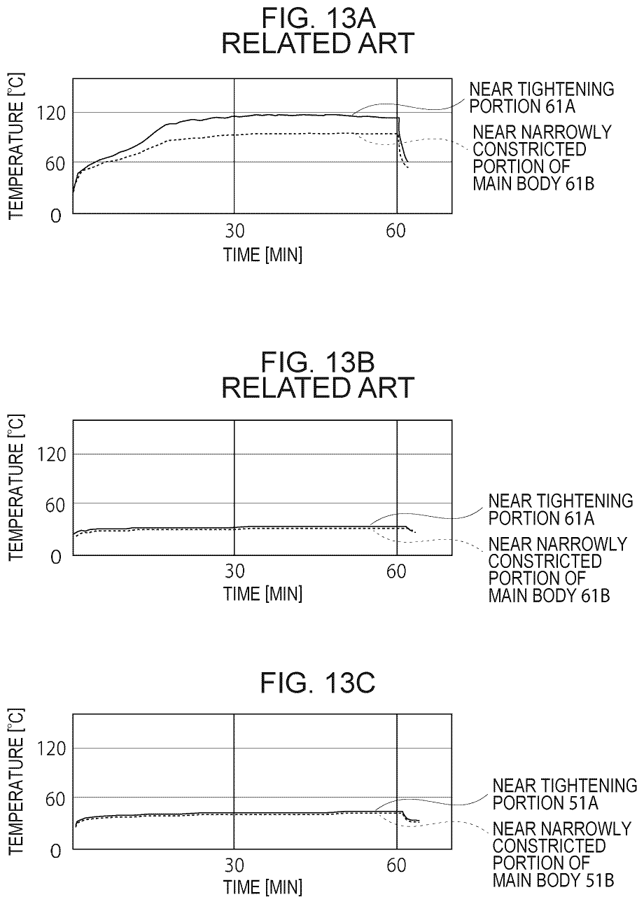

FIG. 13A is a graph illustrating measurement results for temperature changes in the tightening portions 61A and the narrowly constricted portion of the main body 61B, the changes accompanying the elapse of time during which a current under measurement flowed, for the current sensor 60 having the bus bar 61 in which the tightening portion 61A and main body 61B are formed from an Al material.

FIG. 13B is a graph illustrating measurement results for temperature changes in the tightening portions 61A and the narrowly constricted portion of the main body 61B, the changes accompanying the elapse of time during which a current under measurement flowed, for the current sensor 60 having the bus bar 61 in which the tightening portion 61A and main body 61B are formed from a Cu material.

FIG. 13C is a graph illustrating measurement results for temperature changes in the tightening portions 51A and the narrowly constricted portion of the main body 51B, the changes accompanying the elapse of time during which a current under measurement flowed when a current flows under the same conditions, for the current sensor 50, in the reference example, which has the bus bar 51 in which the tightening portion 51A is formed from a Cu material and the main body 51B is formed from an Al material.

It was found from the results illustrated in FIGS. 13A to 13C that in the bus bar 61 formed from only an Al material, when a current under measurement flows, temperature is more likely to rise than in the bus bar 61 formed from only a Cu material. However, in the bus bar 51 in which the tightening portion 51A is formed from a Cu material and the main body 51B is formed from an Al material, the temperature rise due to a flow of the current under measurement was suppressed as in the bus bar 61 in which both the tightening portion 51A and the narrowly constricted portion of the main body 51B are formed from only a Cu material.

It is found from the comparison of the graphs in FIGS. 13A to 13C that in a state in which a current under measurement continuously flows, the temperature change at each portion varies depending on which material is used to form the tightening portion and main body. In the bus bar 61, illustrated in FIG. 13A, in which all are formed from an Al material, heat generation is very large when compared with the bus bar 61, illustrated in FIG. 13B, in which all are formed from a Cu material. Just by forming the tightening portion from a Cu material with the main body left as being formed from an Al material, heat generation in the bus bar 51 was greatly suppressed as illustrated in the graph in FIG. 13C. The reason why temperature finally dropped in each graph after a duration of around 60 minutes is that the flow of the current under measurement was stopped.

From these results, it can be said that the structure in which the tightening portion 51A is formed from a Cu material and the main body 51B is formed from an Al material is effective for reducing the delay of the detection voltage with respect to the current under measurement, improvement of gain, and suppression of a temperature rise when a current under measurement flows.

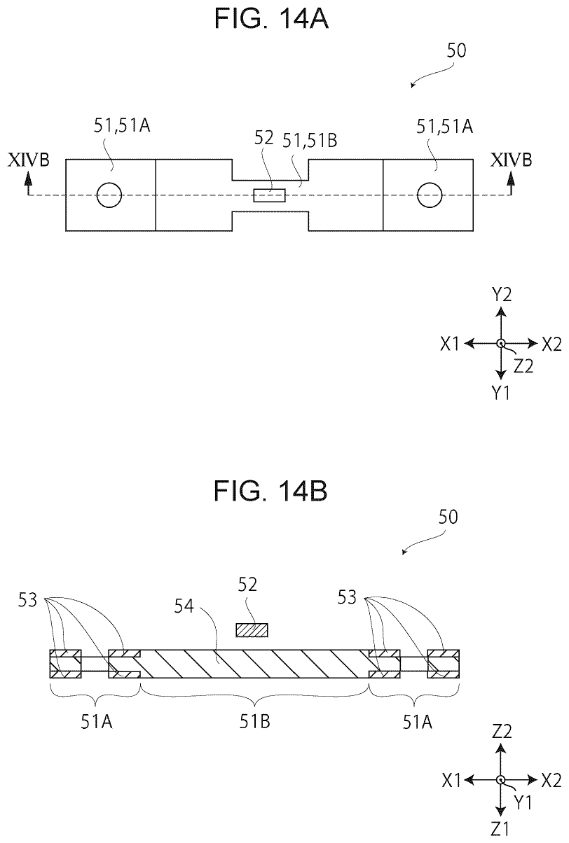

FIG. 14A is a plan view of the current sensor 50 in another reference example. FIG. 14B is a sectional view of the current sensor 50 as taken along line XIVB-XIVB in FIG. 14A. As illustrated in these drawings, even when a structure is taken in which the surface of the Al material of the tightening portion 51A of the bus bar 51 in the current sensor 50 in the Z-axis direction is covered with a material Cu, it is possible to suppress a temperature rise when a current under measurement flows.

The embodiments disclosed in this description are exemplary in all points. The present invention is not restricted to these embodiments. The scope of the present invention is not indicated by the description of only the embodiments described above but is indicated by the scope of the claims. It is intended that meanings equivalent to the scope of the claims and all modifications in the scope are included.

The present invention is useful as a current sensor that is attached to any type of unit and measures a current under measurement to control and monitor the unit.

What is claimed is:

1. A current sensor comprising:
a bus bar in which a current under measurement flows; and
a magnetic detection unit placed so as to face the bus bar, the magnetic detection unit sensing a magnetic field generated around the bus bar; wherein
the bus bar is formed from a laminate material in which a first metal material and a second metal material, which are different types of metal materials, are laminated,
the first metal material has a larger density than the second metal material, and has a smaller electrical resistivity than the second metal material,
the magnetic detection unit is placed so as to face a surface of the bus bar, the surface being formed from the first metal material, and
in a lamination direction, the second metal material has a larger dimension than the first metal material.

2. The current sensor according to claim 1, wherein in the lamination direction, the dimension of the second metal material is 80% or more of the dimension of the lamination material.

3. A current sensor comprising:
a bus bar in which a current under measurement flows; and
a magnetic detection unit placed so as to face the bus bar, the magnetic detection unit sensing a magnetic field generated around the bus bar; wherein
the bus bar is formed from a laminate material in which a first metal material and a second metal material, which are different types of metal materials, are laminated,
the first metal material has a larger density than the second metal material, and has a smaller electrical resistivity than the second metal material,
the magnetic detection unit is placed so as to face a surface of the bus bar, the surface being formed from the second metal material, and
in a lamination direction, the second metal material has a larger dimension than the first metal material.

4. The current sensor according to claim 3, wherein in the lamination direction, the dimension of the second metal material is 60% or more of the dimension of the lamination material.

5. A current sensor comprising a plurality of measurement phases, each of which is composed of a bus bar in which a current under measurement flows, and also has a magnetic detection unit placed so as to face the bus bar, the magnetic detection unit sensing a magnetic field generated around the bus bar, wherein:
the bus bar is formed from a laminate material in which a first metal material and a second metal material, which are different types of metal materials, are laminated;
the first metal material has a larger density than the second metal material, and has a smaller electrical resistivity than the second metal material;
the plurality of measurement phases include a first measurement phase in which the magnetic detection unit is placed so as to face a surface of the bus bar, the surface being formed from the first metal material, and also include a second measurement phase in which the magnetic detection unit placed so as to face a surface of the bus bar, the surface being formed from the second metal material; and
at least one of item I and item II below is satisfied
item I: in a lamination direction, the second metal material has a larger dimension than the first metal material, and
item II: in at least one measurement phase, the bus bar has a bent portion, and the magnetic detection unit is placed at a position at which the magnetic detection unit is capable of sensing induced magnetic fields from two portions positioned with the bent portion interposed between the two portions in the bus bar.

6. The current sensor according to claim 5, wherein second measurement phases are adjacently placed on both sides of the first measurement phase.

7. The current sensor according to claim 5, wherein:
item II above is satisfied;
in the bus bar, the first metal material is provided on a side on which the bent portion is bent; and
the magnetic detection unit faces a layer of the first metal material of the bus bar.

8. The current sensor according to claim 1, wherein:
the first metal material is a copper material; and
the second metal material is an aluminum material.
